(19) United States
(12) Patent Application Publication
(10) Pub. No.: US 2011/0233794 A1
(43) Pub. Date: Sep. 29, 2011

(54) SEMICONDUCTOR DEVICE AND MANUFACTURING METHOD THEREOF

(75) Inventor: YASUAKI IWATA, KANAGAWA (JP)

(73) Assignee: RENESAS ELECTRONICS CORPORATION, Kanagawa (JP)

(21) Appl. No.: 13/070,507

(22) Filed: Mar. 24, 2011

(30) Foreign Application Priority Data
Mar. 29, 2010 (JP) 2010-075169

(51) Int. Cl. H01L 21/603; H01L 23/48

(52) U.S. Cl. 257/782; 438/127; 257/E21.519; 257/E23.01

(57) ABSTRACT

A method of manufacturing a semiconductor device at a good manufacturing efficiency and at a low cost while suppressing the occurrence of voids in the sealing region, the method including the steps of (A) bonding external connection terminals of a semiconductor chip to wirings of a film substrate by hot press bonding, and (B) resin sealing the periphery of the bonded portion of the semiconductor chip and the film substrate, in which the bonding step (A) is performed in a state of adsorbing a portion of the film substrate facing the semiconductor chip from the side opposite the bonding side of the semiconductor chip, and the resin sealing step (B) is performed in a state where the temperature of the semiconductor chip and the film substrate is lowered press is no thermal expansion of the film substrate.

### CROSS-REFERENCE TO RELATED APPLICATION

The disclosure of Japanese Patent Application No. 2010-75169 filed on Mar. 29, 2010 including the specification, drawings and abstract is incorporated herein by reference in its entirety

### BACKGROUND

1. Field of the Invention

The present invention concerns a method of manufacturing a semiconductor device including a step (A) of bonding external connection terminals of a semiconductor chip to wirings of a film substrate by hot press bonding and a step (B) of resin-sealing the periphery of the bonded portion of the semiconductor chip and the film substrate, as well as a semiconductor device manufactured by the manufacturing method.

2. Description of Related Art

Since COF (Chip on Film) mounting can mount a semiconductor chip (IC chip) over a film substrate of high flexibility, this is utilized for application use such as a driver IC of a liquid crystal panel.

An existent method of manufacturing a semiconductor device by COF mounting is to be described with reference to FIG. 4A and FIG. 4B. FIG. 4A is a cross sectional view showing a step of bonding a semiconductor chip to a film substrate and FIG. 4B is a plan view for an adsorption stage.

A bonding device 102 shown in FIG. 4A includes an adsorption stage 130 having in a region outside a semiconductor chip 110 to be bonded, and an adsorption mechanism 131 for adsorbing and holding a film substrate 120, and a bonding tool 140 for pressing the semiconductor chip 110 mounted over the film substrate 120.

The adsorption mechanism 131 includes a plurality of suction holes 131X which are extended and opened in the direction of the height of the adsorption stage 130 and connected to a depressurizing pump and one adsorption hole 131Y of a width larger than the diameter of the suction hole 131X and formed on the top of the plurality of suction holes 131X extending over all of the suction holes 131X. As shown in FIG. 4B, the adsorption mechanism 131 including the plurality of suction holes 131X and one adsorption hole 131Y is arranged in a circular shape in a plan view.

At first, in a state of adsorbing and holding the film substrate 120 to the adsorption stage 130 by using the bonding device 102, bumps 111 (external connection terminals) on the semiconductor chip 110 are bonded to leads (wirings) 121 on the film substrate 120 by hot press bonding.

For easy observation, while the film substrate 120 and the adsorption stage 130 are shown being separated slightly for easy to see, a gap is not actually formed between them.

After detaching the bonded semiconductor chip 110 and the film substrate 120 from the apparatus and returning the temperature about to a room temperature, a treatment of underfill resin sealing is performed by injecting a thermosetting resin to the periphery of the bonded portion between the semiconductor chip 110 and the film substrate 120 and curing the resin by a heat treatment for securing and passivating the semiconductor chip 110.

In COF mounting, since the distance between the semiconductor chip and the film substrate is as close as about 10 and several μm, when the bumps on the semiconductor chip are bonded to the leads on the film by hot press bonding, the film substrate having a thermal expansion coefficient larger than that of the semiconductor chip is thermally expanded. Then as shown in FIG. 4A, a portion of the film substrate facing the semiconductor chip is distorted toward the semiconductor chip in which the semiconductor chip and the film substrate are sometimes adhered partially.

Since the viscosity of the underfill resin is designed to such an optimal value that a capillary phenomenon occurs in a gap between the semiconductor chip and the film substrate, if the gap is partially wide or narrow excessively, this may possibly cause a phenomenon of voids where the resin does not intrude sufficiently into the gap during resin sealing, to leave bubbles in the resin.

With an aim of preventing the occurrence of voids described above, Japanese Patent Application Publication No. 2004-221319 proposes a method of using an adsorption stage having suction holes for adsorbing a portion of the film substrate facing the semiconductor chip, adsorbing a portion of the film substrate facing the semiconductor chip from the outside and bonding the semiconductor chip and the film substrate in a state of distorting the film substrate such that the gap between the semiconductor chip and the film substrate is increased (FIG. 1A), and

injecting a sealing resin (underfill resin) in the distorted state as it is (FIG. 1B) and

pushing the distorted film substrate from the outside by using a pushing out tool thereby pushing out the excess sealing resin from the lateral side of the semiconductor chip.

### SUMMARY

However, the method described in Japanese Patent Application Publication No. 2004-221319 involves the following problems.

At first, in the method described in Japanese Patent Application Publication No. 2004-221319, since the sealing resin is injected while distorting the film substrate (FIG. 1B), adsorption has to be continued from the outside of the portion of the film substrate opposing the semiconductor chip also upon injection of the sealing resin. Therefore, it is necessary to perform the resin sealing in a state where the semiconductor chip and the film substrate are set as they are to the bonding device.

Further, since the sealing resin is usually thermosetting, resin sealing has to be performed after lowering the temperature of the semiconductor chip and the film substrate, which was increased upon bonding to a necessary temperature. Therefore, in the method described in Japanese Patent Application Publication No. 2004-221319, it is necessary that the adsorption stage is used as it is while dissipating the heat of the semiconductor chip and the film substrate, the bonding device for curing the sealing resin is heated and, after the completion of curing for the sealing resin, the bonding device has to be heated in the next bonding to a temperature for bonding. That is, in the method described in Japanese Patent Application Publication No. 2004-221319, it is necessary to rise and lower the temperature of the bonding device repetitively and it has to be waited till a predetermined temperature is reached on every step.

Resin sealing to a gap of about 10 and several μm between the semiconductor chip and the film substrate takes a much time of from several seconds to ten seconds or more even when a resin having a viscosity optimized for the gap is used. The resin sealing step was much time consuming in the entire mounting steps so far. Then, it is not efficient to perform the resin sealing after waiting for the lowering of the temperature while setting the semiconductor chip and the film substrate to the bonding device.

With the reasons described above, according to the method of Japanese Patent Application Publication No. 2004-221319, the operation efficiency of the apparatus is poor, a lot of expensive adsorption stages have to be provided, the manufacturing efficiency and the energy efficiency are poor, and the manufacturing cost is high.

Secondly, in the method described in Japanese Patent Application Publication No. 2004-221319, it is indispensable for the step of pushing out the resin after injection of the sealing resin (FIG. 1C). Since the number of step is increased, the manufacturing efficiency is poor and the manufacturing cost is increased.

Thirdly, since the viscosity of the sealing resin is designed to an optimum value for the occurrence of a capillary phenomenon in the gap between the semiconductor chip and the film substrate, if the gap is partially wide excessively, this rather causes occurrence of voids. Accordingly, in the method of Japanese Patent Application Publication No. 2004-221319 of injecting the sealing resin while distorting the film substrate as it is, the resin cannot be injected as designed and voids are tended to occur. Then, also when the resin is pushed up from below, there is a high possibility that voids near the central portion of the semiconductor chip do not escape but remain in situ. Accordingly, the yield is poor and the manufacturing cost is increased.

A method of manufacturing a semiconductor device according to an aspect of the invention includes:

(A) bonding external connection terminals of a semiconductor chip to wirings of a film substrate by hot press bonding; and

(B) resin sealing the periphery of the bonded portions between the semiconductor chip and the film substrate in which,

the step (A) is performed in a state of adsorbing a portion of the film substrate facing the semiconductor chip from the side opposite to the bonding side of the semiconductor chip, and

the step (B) is performed in a state where the temperature of the semiconductor chip and the film substrate is lowered and there is no thermal expansion in the film substrate.

A semiconductor device of the invention is manufactured by the method of manufacturing the semiconductor device of the invention described above.

In the invention, since the bonding step (A) is performed in a state of adsorbing a portion of the film substrate facing the semiconductor chip from the side opposite to the bonding side of the semiconductor chip, there is no possibility that the gap between the semiconductor chip and the film substrate is narrowed and they are adhered to each other in the step, and bonding can be performed favorably. Accordingly, resin sealing can be performed as designed in the next resin sealing step (B) and generation of voids in the sealing resin can be suppressed.

According to the invention, since the resin sealing step (B) is performed in a state where the temperature of the film substrate is lowered and there is no thermal expansion of the substrate, it is not necessary to continue adsorption of the film substrate also after the bonding step (A), and the semiconductor chip and the film substrate are detached from the bonding device after the end of the bonding step (A) and can proceed to the next step, so that the manufacturing efficiency and the energy efficiency are good and manufacturing at lower cost is possible.

The present invention can provide a method of manufacturing a semiconductor device including the step (A) of bonding the external connection terminals of the semiconductor chip to the wirings of the film substrate by hot press bonding and the step (B) of resin sealing the periphery of the bonded portion between the semiconductor chip and the film substrate, the method being capable of manufacturing at a good manufacturing efficiency and at a lower cost and capable of suppressing the occurrence of voids in the sealing region.

### BRIEF DESCRIPTION OF THE DRAWINGS

FIG. 1A to FIG. 1E are step charts for the method of manufacturing a semiconductor device in an embodiment according to the invention;

FIG. 2 is a plan view of an adsorption stage used in the method of a semiconductor device of an embodiment according to the invention;

FIG. 3A and FIG. 3B are views showing a modified example of a method of manufacturing a semiconductor device; and

FIG. 4A and FIG. 4B are views showing an existent method of manufacturing a semiconductor device.

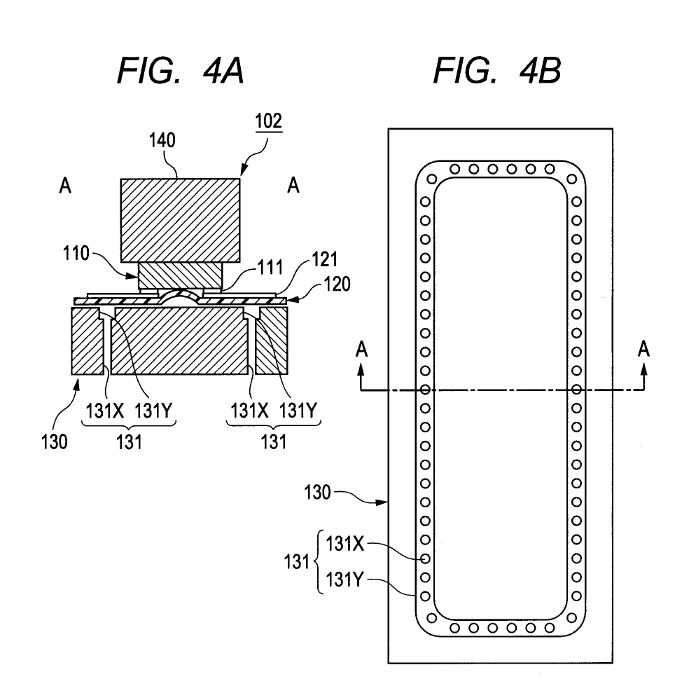

### PREFERRED EMBODIMENTS OF THE INVENTION

A method of manufacturing a semiconductor device of an embodiment according to the invention is to be described with reference to the drawings.

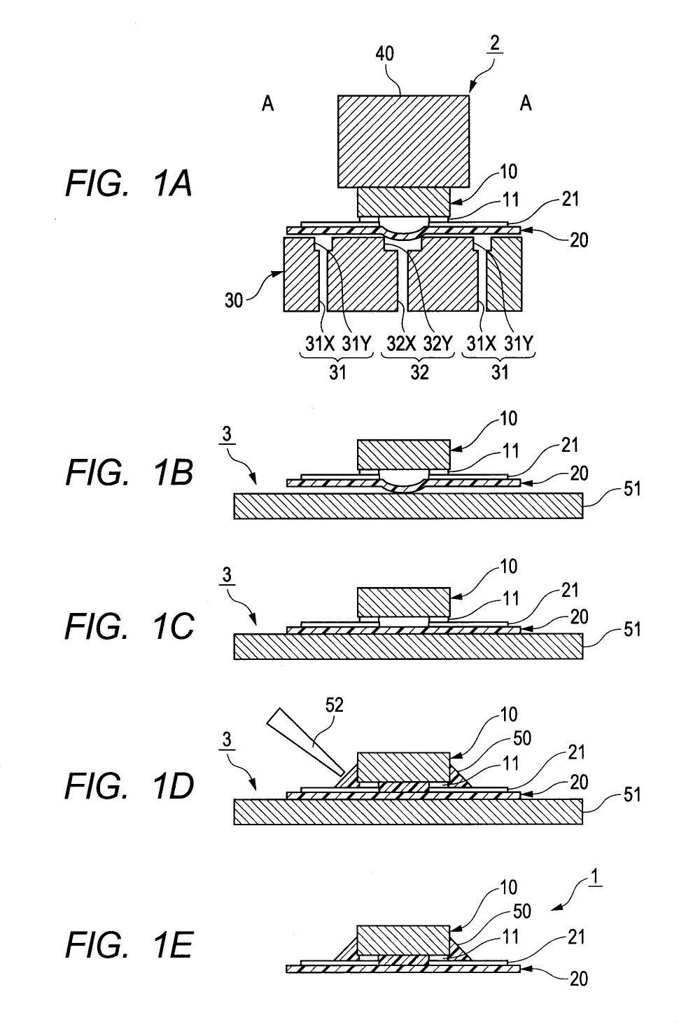

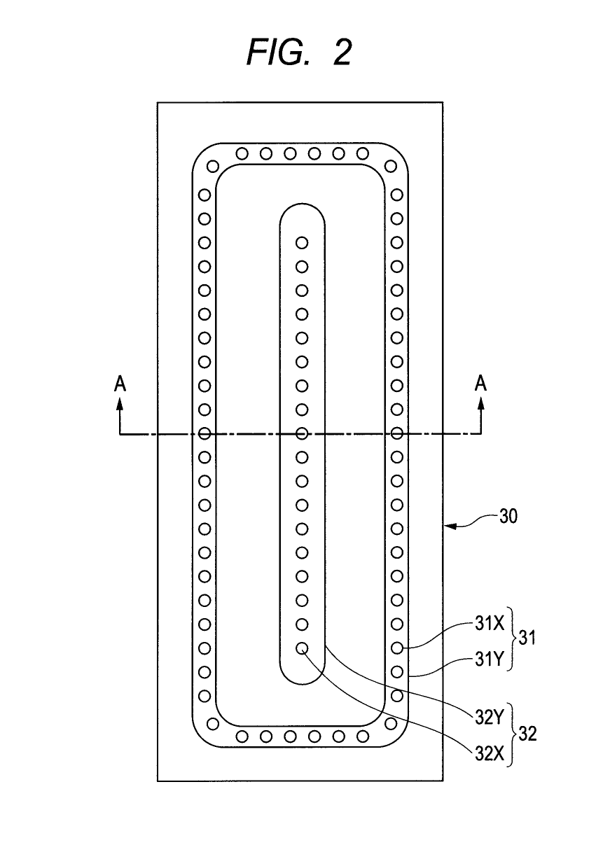

FIG. 1A to FIG. 1E are step charts and FIG. 2 is a plan view of an adsorption stage. FIG. 1A to FIG. 1E are cross sectional views corresponding to cross section A-A in FIG. 2. In the drawings, scaling, etc. for each components are made different properly from actual ones in order for easy visibility in view of the drawings. Further, in the cross sectional views, hatchings are optionally omitted.

In this embodiment, description is to be made to an example for manufacturing a semiconductor device 1 by COF (Chip on Film) mounting.

As shown in FIG. 1A to FIG. 1E,

a method of manufacturing the semiconductor device 1 of this embodiment includes:

a step (A) of bonding bumps (external connection terminals) 11 of a semiconductor chip (IC chip) 10 to leads (wirings) 21 of a film substrate 20 by hot press bonding, and

a step (B) of resin-sealing the periphery of a bonded portions between the semiconductor chip 10 and the film substrate 20 with a sealing resin (underfill resin) 50.

### <Step (A)>

In this embodiment, as shown in FIG. 1A, the step (A) is performed by using a bonding device 2 having an adsorption stage 30 for adsorbing and holding a film substrate 20 and a bonding tool 40 for pressing the semiconductor chip 10 mounted over the film substrate 20.

For easy visibility, while the film substrate 20 and the adsorption stage 30 are illustrated being apart slightly from each other, no gap is actually formed between them.

As shown in FIG. 1A and FIG. 2, in the adsorption stage 30, are provided a first adsorption mechanism 31 for adsorbing and holding the film substrate 20 in a region outside the semiconductor chip 10 to be bonded and a second adsorption mechanism 32 of adsorbing and holding the film substrate 20 to a region opposing to the semiconductor ship 10 to be bonded.

The first adsorption mechanism 31 includes a plurality of first suction holes 31X extended and opened in the direction of the height of the adsorption stage 30 and connected with a depressurizing pump (not illustrated) and one first adsorption hole 31Y of a width larger than the diameter of the first suction hole 31X formed above the plurality of the first suction holes 31X and extending all of the first suction holes 31X. As shown in FIG. 2, the first adsorption mechanism 31 including a plurality of first suction holes 31X and one first adsorption hole 31Y is arranged in a circular shape in a plan view.

The second adsorption mechanism 32 includes a plurality of second suction holes 32X extended and opened in the direction of the height of the adsorption stage 30 and connected with a depressurization pump (not illustrate), and a second adsorption hole 32Y of a width larger than the diameter of the second suction hole 32X formed above the plurality of the second suction holes 32X and extending all of the second suction holes 32X. As shown in FIG. 2, the second adsorption mechanism 32 including the plurality of second suction holes 32X and one second adsorption hole 32Y is arranged in a central portion of the adsorption stage 30 in a linear shape in a plan view.

In this embodiment, it is designed as: diameter of the first suction hole 31X=the diameter of the second suction hole 32X, and the diameter of the second adsorption hole 32Y>the diameter of the first adsorption hole 31Y. The diameter of the second adsorption hole 32Y is designed smaller than the pitch of the bumps 11 of the semiconductor chip 10.

The inside of the bonding device 2 is heated and set to a temperature necessary for bonding (usually, about 380 to 420° C.).

In this embodiment, the outer peripheral portion and a portion facing the semiconductor chip 10 of the film substrate 20 are adsorbed from the side opposite the bonding side of the semiconductor chip 10 using the bonding device 2 having the adsorption mechanisms described above.

In the state described above, the semiconductor chip 10 is mounted over the film substrate 20. In this case, the semiconductor chip 10 is mounted over the film substrate 20 such that the bumps 11 of the semiconductor chip 10 are situated on leads 21 of the film substrate 20.

In the state described above, when the semiconductor chip 10 is pressed to the side of the film substrate 20 by the bonding tool 40, the bumps 11 of the semiconductor chip 10 are hot press bonded to the leads 21 of the film substrate 20 and they are bonded.

In the bonding step (A), while the film substrate 20 thermally expands by the heat during bonding, since the portion slackened by expansion is pulled by the second adsorption mechanism 32, it does not direct toward the semiconductor chip 10. In this embodiment, since it is designed as: diameter of the second adsorption hole 32Y>diameter of first adsorption hole 31Y, the portion of the film substrate 20 facing the semiconductor chip 10 is pulled to the side of the second adsorption hole 32Y and distorted. Under the effect, even when there is no possibility that the gap between the semiconductor chip 10 and the film substrate 20 is narrowed and they are adhered to each other, and bonding can be performed favorably.

### <Step (B)>

In this embodiment, the step (B) is performed in a state where the temperature of the semiconductor chip 10 and the film substrate 20 is lowered and there is no thermal expansion of the film substrate 20.

During waiting for temperature lowering of the semiconductor chip 10 and the film substrate 20, the position for mounting the semiconductor chip 10 and the film substrate 20 is not restricted.

For obtaining a good manufacturing efficiency, it is preferred to detach the semiconductor chip 10 and the film substrate 20 after the completion of the bonding from the bonding device 2, and place them on a stage 51 of the resin sealing device 3 as shown in FIG. 1B and wait for the lowering of the temperature of the semiconductor 10 and the film substrate 20.

The temperature of the semiconductor chip 10 and the film substrate 20 may be lowered till a state where there is no thermal expansion of the film substrate 20 and the temperature is preferably lowered to a normal temperature or a temperature approximate thereto, specifically, to about 20 to 50° C.

It is sufficient to lower the temperature of the semiconductor chip 10 and the film substrate 20 by spontaneous cooling.

In the present specification, “state where there is no thermal expansion of the film substrate 20” means a state where a sufficient gap is present between the film substrate 20 and the semiconductor 10 to such an extent that the step (B) can be performed favorably.

In a state where thermal expansion or distortion of the film substrate 20 is eliminated, a sealing resin (underfill resin) 50 is injected from an injection nozzle 52 of the resin sealing device 3 to resin seal the periphery of the bonded portion between the semiconductor chip 10 and the film substrate 20 with a sealing resin 50 as shown in FIG. 1D. The viscosity of the sealing resin 50 is adjusted so as to cause optimal capillary phenomenon in the gap between the semiconductor chip 10 and the film substrate 20.

The sealing resin 50 is not particularly restricted and a thermosetting resin is used usually. In this case, after injecting the sealing resin 50, it is heated to a curing temperature thereby curing the sealing resin 50. In this embodiment, since there is no possibility that the gap between the semiconductor chip 10 and the film substrate 20 is narrowed and they are adhered to each other, resin sealing can be performed as designed and occurrence of voids is suppressed.

As described above, a semiconductor device 1 shown in FIG. 1E is manufactured.

In this embodiment, since the bonding step (A) is performed in a state of adsorbing the portion of the film substrate 20 facing the semiconductor chip 10 on the side of the semiconductor chip 10 opposite the bonding side, there is no possibility that the gap between the semiconductor chip 10 and the film substrate 20 is narrowed and they are adhered to each other, and bonding can be performed favorably. Therefore, designed resin sealing can be performed as it is in the next resin sealing step (B), and occurrence of voids in the sealing resin 50 is suppressed.

In this embodiment, since the resin sealing step (B) is performed in a state where the temperature of the film substrate 20 is lowered and thermal expansion is eliminated, it is no more necessary to continue adsorption of the film substrate 20 after the bonding step (A). Then, the semiconductor chip 10. Then the film substrate 20 can be detached from the bonding device 2 after the completion of the bonding step (A) and they can be proceeded to the next step, so that the manufacturing efficiency and energy efficiency are good and products can be manufactured at lower cost.

This embodiment can provide a method of manufacturing the semiconductor device 1 at a good manufacturing efficiency and at lower cost and suppressing the occurrence of voids in the sealing resin 50.

### Modified Example

While the embodiment described above is designed as: diameter of the second adsorption hole 32Y>diameter of the first adsorption hole 31Y, it may be designed as: diameter of the second adsorption hole 32Y≦diameter of the first adsorption hole 31Y. It may be also designed such that the second adsorption hole 32Y is not formed and the second adsorption mechanism 32 may be comprised only of the second adsorption hole 32X.

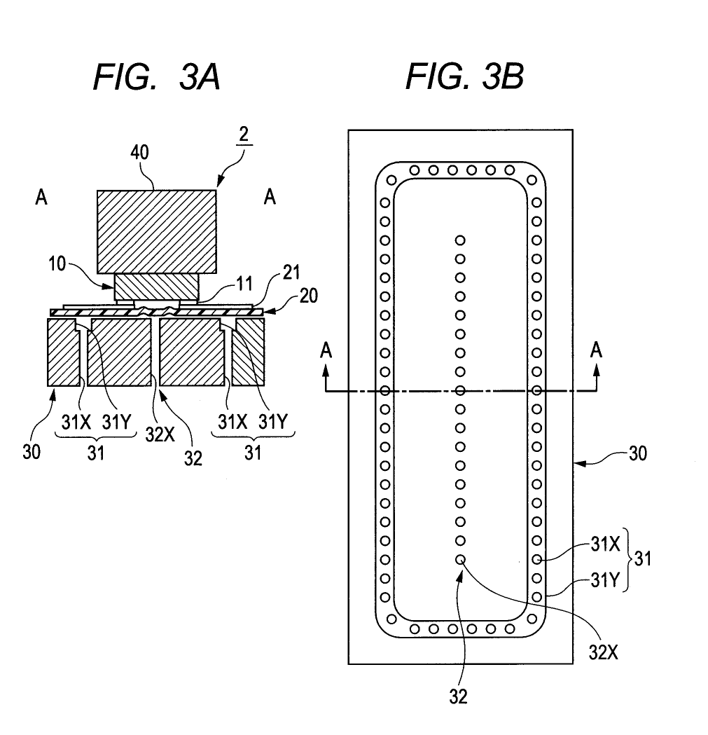

FIG. 3A and FIG. 3B are an example of constituting the second adsorption mechanism 32 only of a plurality of second suction holes 32X. FIG. 3A is a view corresponding to FIG. 1A and FIG. 3B is a view corresponding to FIG. 2.

Also in the modification described above, since the portion of the film substrate 20 that is slackened by thermal expansion by the heat during bonding is pulled by the second adsorption mechanism 32, the expanded portion does not direct to the semiconductor chip 10 and the same effect as in the embodiment described above is obtained. However, in a case where the diameter of the second adsorption mechanism 32 is small, the film substrate 20 does not distort greatly toward the second adsorption mechanism 32.

Even when the diameter of the second adsorption mechanism 32 is decreased, there is no possibility that the gap between the semiconductor chip 10 and the film substrate 20 is narrowed in the step of (A) and they are adhered to each other and bonding can be performed favorably. Accordingly, resin sealing can be performed as designed in the next resin sealing step (B) and the occurrence of voids in the sealing resin 50 can be suppressed.

When the diameter of the second adsorption mechanism 32 is made smaller, this can cope with the mounting of a semiconductor chip 10 with the bump pitch smaller than that of the embodiment described above.

Further, the present invention can be modified optionally within a range not departing from the gist of the invention.

What is claimed is:

1. A method of manufacturing a semiconductor device comprising:
(A) bonding external connection terminals of a semiconductor chip to wirings of a film substrate by hot press bonding; and
(B) resin sealing the periphery of the bonded portion of the semiconductor chip and the film substrate,
wherein the step (A) is performed in a state of adsorbing a portion of the film substrate facing the semiconductor chip from the side opposite to the bonding side of the semiconductor chip, and
wherein the step (B) is performed in a state where the temperature of the semiconductor chip and the film substrate is lowered there is no thermal expansion the film substrate.

2. A semiconductor device manufactured by the method of manufacturing the semiconductor device according to claim 1.
